(19) United States
(12) Patent Application Publication
(10) Pub. No.: US 2005/0045941 A1
(43) Pub. Date: Mar. 3, 2005

(54) Nonvolatile semiconductor memory and method of fabricating the same

(75) Inventors: Koichi Kurita, Kanagawa (JP); Mitsuhiro Noguchi, Kanagawa (JP); Akira Goda, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/893,295

(22) Filed: Jul. 19, 2004

(30) Foreign Application Priority Data
Jul. 23, 2003 (JP) 2003-200343

(51) Int. Cl. H01L 29/788

(52) U.S. Cl. 257/315

(57) ABSTRACT

According to the present invention, there is provided a nonvolatile semiconductor memory capable of electrically writing and erasing information, comprising: a semiconductor substrate; source and drain regions formed at a predetermined spacing in a surface portion of said semiconductor substrate; a channel region positioned between said source and drain regions; a floating gate electrode formed on said cannel region via a first insulating film; a control gate electrode including a semiconductor layer formed on said floating gate electrode via a second insulating film, and a metal layer formed on said semiconductor layer; and an oxidation-resistant third insulating film formed on said control gate electrode, wherein the nonvolatile semiconductor memory further comprises an oxidation-resistant fourth insulating film so formed as to cover at least sidewalls of said metal layer, and said fourth insulating film is formed from the sidewalls of said metal layer to at least portions of sidewalls of said semiconductor layer of said control gate electrode.

### CROSS REFERENCE TO RELATED APPLICATION

This application is based upon and claims benefit of priority under 35 USC § 119 from the Japanese Patent Application No. 2003-200343, filed on Jul. 23, 2003, the entire contents of which are incorporated herein by reference.

### RELATED ART

The present invention relates to a nonvolatile semiconductor memory and a method of fabricating the same.

A nonvolatile semiconductor memory is developed in which electric charge injected from a channel region into a charge storage layer via a tunnel insulating film by a tunnel current is used as a digital bit information storage, and information is read out by measuring that conductance change of a MOSFET, which corresponds to the charge amount.

This nonvolatile semiconductor memory uses a stacked structure of a metal and polysilicon. The metal is tungsten silicide (Wsi) having an Si/W composition ratio of 2.4 or more.

The cell reliability worsens if this Wsi is changed to a material having a lower resistance, i.e., Wsi having an Si/W composition ratio of 2.4 or less or W, in order to shorten the gate delay and reduce the write time by lowering the resistance of the control gate electrode.

In connection with this phenomenon, the problem of the conventional nonvolatile semiconductor memory will be explained below with reference to FIG. 29.

First, a silicon oxide film, for example, is formed as a tunnel oxide film 21 on a P-type semiconductor substrate 10, and a phosphorus-doped polysilicon film, for example, is formed as a floating gate electrode 22 on the tunnel oxide film 21.

An interpoly insulating film 23 is stacked on top of the structure, and a polysilicon film is formed as a control gate electrode 24 on the interpoly insulating film 23. On this polysilicon film, a control gate resistance decreasing metal film 25 made of Wsi or W is formed.

Assume that a metal made of Wsi having an Si/W composition ratio of 2.4 or less or W is used as the control gate resistance decreasing metal film 25 to further decrease the resistance.

On the control gate resistance decreasing metal film 25, a silicon nitride film, for example, is formed as a mask insulating film 26 which functions as an etching mask material during gate electrode formation.

The stacked structure thus formed is patterned from the polysilicon film as the floating gate electrode 22 to the silicon nitride film as the mask insulating film 26 by lithography and anisotropic etching.

Subsequently, damage recovery is performed by anisotropic etching, and, in order to prevent a leakage current from the polysilicon film as the floating gate electrode 22 via the gate sidewalls, the sidewalls of the floating gate electrode 22 are oxidized within the range of, e.g., 5 to 20 nm.

If the control gate resistance decreasing metal film 25 is made of Wsi or W, the control gate resistance decreasing metal film 25 oxidizes more than the polysilicon film as the floating gate electrode 22 under the normal wet oxidation, dry oxidation, or ISSG oxidation conditions. As shown in FIG. 29, therefore, a silicon oxide film 43 formed on the sidewalls of the control gate resistance decreasing metal film 25 and containing the metal elements expands more than sidewall oxide films 41 and 42 formed on the side surfaces of the polysilicon film as the floating gate electrode 22 and on the side surfaces of the polysilicon film as the control gate electrode 24.

Especially when the control gate resistance decreasing metal film 25 is made of Wsi having an Si/W composition ratio of 2.4 or less, a conductive tungsten oxide 61 abnormally grows in the sidewall oxidation step.

On the other hand, when the control gate resistance decreasing metal film 25 is made of W, the control gate resistance decreasing metal film 25 readily oxidizes in a heating step at 700° C. or higher, and a conductive tungsten oxide 61 abnormally grows.

In either case, the spacing between the control gate resistance decreasing metal film 25 (WL1) and control gate resistance decreasing metal film 25 (WL2) of the adjacent control gates is narrowed by the conductive tungsten oxide film 61. This produces a defective breakdown voltage between data selecting lines WL1 and WL2.

In addition, after gate sidewall oxidation, an N-type impurity such as phosphorus or arsenic is usually ion-implanted to form source/drain regions 28. If the tungsten oxide film 61 is formed, however, shadowing occurs when ion implantation is performed, so the N-type impurity cannot be well supplied to the underlying semiconductor substrate 10 any longer.

Accordingly, as shown in FIG. 29, a portion having no impurity diffusion layer 51 serving as a source or drain region is formed, and this makes the device unable to operate as a transistor.

When an interlayer dielectric film such as a silicon oxide film or silicon nitride film is buried between the gate electrodes after that, the expanding tungsten oxide 61 worsens the burying properties, and an air gap called a seam forms. Also, shadowing is caused by the presence of the tungsten oxide 61, and an air gap in which no interlayer dielectric film is formed forms on the sidewall of the floating gate.

When an air gap forms very close to the charge storage layer as described above, the etching depth of the interlayer dielectric film largely changes from that when no such air gap is present. This extremely worsens the controllability of the etching depth when a contact is formed in this portion later.

Furthermore, when memory cells are formed adjacent to each other in the direction perpendicular to the paper of FIG. 29, a conductor for forming a contact electrode enters along the air gap. This may cause a shortcircuit between the adjacent cells.

Note that non-patent reference 1 (to be described later) is disclosed in connection with selective oxidation of polysilicon and W.

This reference discloses a method by which polysilicon sidewalls oxidize more than W by selective oxidation at 800° C. to 850° C.

In this method, however, low-temperature oxidation normally performed at 850° C. is used, so the viscosity of the oxide film is high. Consequently, as shown in FIG. 29, after the oxidation an end portion 200 of the floating gate electrode 22 positioned in the contact point between the sidewall oxide film 41 and tunnel oxide film 21 is sharply pointed.

This shape becomes significant especially when the phosphorus concentration in the polysilicon of the floating gate electrode 22 is high, and so the oxidation rate is high.

When this device is used as a nonvolatile semiconductor memory, therefore, field concentration occurs in the sharp-pointed portion 200 when data is erased by extracting electrons from the floating gate electrode 22. This allows electrons to be discharged from the sharp-pointed portion more easily than from a flat portion into the semiconductor substrate 10 or impurity diffusion layer 51.

As a consequence, the flow of electrons concentrates to the sharp-pointed portion, so this portion rapidly deteriorates when write and erase are repeated by using the device as a flash memory. This degrades the reliability.

Also, patent reference 1 (to be described later) discloses a technique related to the present invention.

This reference discloses a technique which, in a nonvolatile semiconductor memory using tungsten as a control gate, prevents abnormal oxidation of tungsten by covering the control gate with a nitride film.

Unfortunately, this technique has the following problem. As shown in FIG. 9 of this reference, a nitride film 49a covers the sidewalls of a control gate polysilicon layer 39, but does not cover any sidewalls of an ONO film 37 and floating gate polysilicon film 35 at all.

This reference does not disclose the shape of a post-oxide film which is formed on the floating gate polysilicon film 35 by post-oxidation. However, when the post-oxidation step is performed, the sidewalls of the floating gate polysilicon layer 35 positioned below the ONO film 37 oxidize to form bird's beaks. Consequently, the sidewalls of the control gate polysilicon layer 39 positioned above the ONO film 37 do not oxidize at all.

This makes etching damage recovery in the upper portion of the ONO film 37 unsatisfactory, and causes an insufficient breakdown voltage and unsatisfactory reliability.

In a nonvolatile semiconductor memory, the increase in thickness of the ONO film 37 can be prevented by decreasing the post-oxidation amount and thereby decreasing the size of the bird's beaks formed at the upper and lower edges of the sidewalls of the ONO film 37. Since this increases the coupling ratio defined by C_{ONO}/(C_{ONO}+Cₒₓ), the data write characteristics (program characteristics) improve. C_{ONO} is the capacitance of the ONO film 37, and Cₒₓ is the capacitance of a tunnel oxide film 33a.

Unfortunately, bird's beaks form on the sidewalls of the floating gate polysilicon layer 35 positioned below the ONO film 37 disclosed in FIG. 9 of this reference. Accordingly, the write characteristics are also unsatisfactory.

That is, the reliability pertaining to the breakdown voltage and the program characteristics have a tradeoff relationship in accordance with whether to form bird's beaks at the upper and lower edges of the sidewalls of the ONO film 37. The technique disclosed in this reference cannot satisfy either.

Non-Patent Reference 1:

S. choi, “High Manufacturable Sub-100 nm DRAM Integrated with Full Functionality”, IEDM2002

Patent Reference 1:

Japanese Patent Laid-Open No. 2003-31708

As described above, when the control gate resistance decreasing metal film 25 is formed by using a metal made of Wsi having an Si/W composition ratio of 2.4 or less or by using W, a conductive tungsten oxide 61 abnormally grows in the gate sidewall oxidation step. This deteriorates the breakdown voltage between the control gates.

Also, the floating gate electrode 22 positioned in the contact point between the sidewall oxide film 41 and tunnel oxide film is sharply pointed. This accelerates deterioration by field concentration, and lowers the reliability.

Furthermore, the prior art which, in a device using tungsten as a control gate, prevents abnormal oxidation of tungsten by covering the control gate with a nitride film is proposed. However, this prior art has the problems of poor reliability and program characteristics.

### SUMMARY OF THE INVENTION

According to one aspect of the present invention, there is provide a nonvolatile semiconductor memory capable of electrically writing and erasing information, comprising:
a semiconductor substrate;
source and drain regions formed at a predetermined spacing in a surface portion of said semiconductor substrate;
a channel region positioned between said source and drain regions;
a floating gate electrode formed on said cannel region via a first insulating film;
a control gate electrode including a semiconductor layer formed on said floating gate electrode via a second insulating film, and a metal layer formed on said semiconductor layer; and
an oxidation-resistant third insulating film formed on said control gate electrode,
wherein the nonvolatile semiconductor memory further comprises an oxidation-resistant fourth insulating film so formed as to cover at least sidewalls of said metal layer, and
said fourth insulating film is formed from the sidewalls of said metal layer to at least portions of sidewalls of said semiconductor layer of said control gate electrode.

According to one aspect of the present invention, there is provide a nonvolatile semiconductor memory, comprising:
a semiconductor substrate;
source and drain regions formed at a predetermined spacing in a surface portion of said semiconductor substrate;
a channel region positioned between said source and drain regions;
a floating gate electrode formed on said cannel region via a first insulating film;
a control gate electrode including a semiconductor layer formed on said floating gate electrode via a second insulating film, and a metal layer formed on said semiconductor layer;
an oxidation-resistant third insulating film formed on said control gate electrode; and
an oxidation-resistant fourth insulating film formed as to cover sidewalls of said metal layer, and to cover regions from sidewalls of said semiconductor layer of said control gate electrode to portions of sidewalls of said floating gate electrode.

According to one aspect of the present invention, there is provide a nonvolatile semiconductor memory fabrication method, comprising:
forming, on a semiconductor substrate, a first insulating film, a conductive film serving as a floating gate electrode, a second insulating film, a semiconductor layer and metal layer serving as a control gate electrode, and a third insulating film in the order named;
patterning the third insulating film, the metal layer, and an upper portion of the semiconductor layer into a shape of a gate electrode;
forming a fourth insulating film on surfaces of the third insulating film, metal layer, and semiconductor layer;
etching the fourth insulating film such that the fourth insulating film remains on sidewalls of the third insulating film, metal layer, and semiconductor layer, and does not remain on an upper surface of the semiconductor layer;
etching and patterning the semiconductor layer, metal layer, second insulating film, and conductive film into a shape of an electrode by using the third insulating film as a mask, thereby forming the floating gate electrode and control gate electrode;
performing a post-oxidation process to form a sidewall oxide film on portions of sidewalls of the semiconductor layer, which are not covered with the fourth insulating film, and on sidewalls of the conductive film; and
ion-implanting an impurity in a surface portion of the semiconductor substrate by using the floating gate electrode and control gate electrode as masks, thereby forming source and drain regions.

### BRIEF DESCRIPTION OF THE DRAWINGS

FIG. 1 is a longitudinal sectional view showing the sectional structure of a nonvolatile semiconductor memory according to the first embodiment of the present invention;

FIG. 2 is a longitudinal sectional view showing the section in a certain step of the nonvolatile semiconductor memory according to the first embodiment;

FIG. 3 is a longitudinal sectional view showing the section in a certain step of the nonvolatile semiconductor memory according to the first embodiment;

FIG. 4 is a longitudinal sectional view showing the section in a certain step of the nonvolatile semiconductor memory according to the first embodiment;

FIG. 5 is a longitudinal sectional view showing the section in a certain step of the nonvolatile semiconductor memory according to the first embodiment;

FIG. 6 is a longitudinal sectional view showing the section in a certain step of the nonvolatile semiconductor memory according to the first embodiment;

FIG. 7 is a longitudinal sectional view showing the section in a certain step of the nonvolatile semiconductor memory according to the first embodiment;

FIG. 8 is a longitudinal sectional view showing the section in a certain step of the nonvolatile semiconductor memory according to the first embodiment;

FIG. 9 is a longitudinal sectional view showing the section in a certain step of the nonvolatile semiconductor memory according to the second embodiment;

FIG. 10 is a longitudinal sectional view showing the section in a certain step of the nonvolatile semiconductor memory according to the second embodiment;

FIG. 11 is a longitudinal sectional view showing the section in a certain step of the nonvolatile semiconductor memory according to the second embodiment;

FIG. 12 is a longitudinal sectional view showing the section in a certain step of the nonvolatile semiconductor memory according to the second embodiment;

FIG. 13 is a longitudinal sectional view showing the section in a certain step of the nonvolatile semiconductor memory according to the second embodiment;

FIG. 14 is a longitudinal sectional view showing the section in a certain step of the nonvolatile semiconductor memory according to the second embodiment;

FIG. 15 is a longitudinal sectional view showing the section in a certain step of the nonvolatile semiconductor memory according to the second embodiment;

FIG. 16 is a longitudinal sectional view showing the section in a certain step of the nonvolatile semiconductor memory according to the third embodiment;

FIG. 17 is a longitudinal sectional view showing the section in a certain step of the nonvolatile semiconductor memory according to the third embodiment;

FIG. 18 is a longitudinal sectional view showing the section in a certain step of the nonvolatile semiconductor memory according to the third embodiment;

FIG. 19 is a longitudinal sectional view showing the section in a certain step of the nonvolatile semiconductor memory according to the third embodiment;

FIG. 20 is a longitudinal sectional view showing the section in a certain step of the nonvolatile semiconductor memory according to the third embodiment;

FIG. 21 is a longitudinal sectional view showing the section in a certain step of the nonvolatile semiconductor memory according to the third embodiment;

FIG. 22 is a longitudinal sectional view showing the section in a certain step of the nonvolatile semiconductor memory according to the third embodiment;

FIG. 23 is a circuit diagram showing the circuit configuration of the nonvolatile semiconductor memory according to the fourth, fifth or sixth embodiment;

FIG. 24 is a planar view showing a planar arrangement of the nonvolatile semiconductor memory according to the fourth, fifth or sixth embodiment;

FIG. 25 is a longitudinal sectional view showing the sectional structure taken along a line B-B in FIG. 24 of a nonvolatile semiconductor memory according to the fourth embodiment;

FIG. 26 is a longitudinal sectional view showing the sectional structure taken along a line A-A in FIG. 24 of a nonvolatile semiconductor memory according to the fourth embodiment;

FIG. 27 is a longitudinal sectional view showing the sectional structure taken along the line A-A in FIG. 24 of a nonvolatile semiconductor memory according to the fifth embodiment;

FIG. 28 is a longitudinal sectional view showing the sectional structure taken along the line A-A in FIG. 24 of a nonvolatile semiconductor memory according to the sixth embodiment; and

FIG. 29 is a longitudinal sectional view showing the section in a certain step of the conventional nonvolatile semiconductor memory.

### DETAILED DESCRIPTION OF THE INVENTION

Embodiments of the present invention will be described below with reference to the accompanying drawings.

(A) First Embodiment

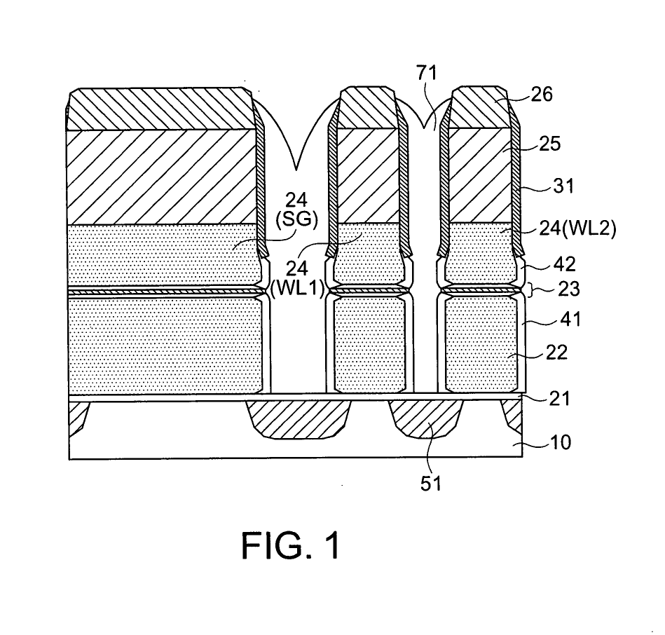

FIG. 1 shows the sectional structure of a nonvolatile semiconductor memory according to the first embodiment of the present invention.

This embodiment has the features that all the sidewalls of a control gate resistance decreasing metal film 25 and portions of the sidewalls of a polysilicon film serving as a control electrode 24 are covered with a sidewall insulating film made of an oxidation-resistant film, e.g., a silicon nitride film or silicon oxide film.

Referring to FIG. 1, on a P-type silicon semiconductor substrate 10 having a boron or indium impurity concentration of 10¹⁴ to 10¹⁹ cm⁻³, 10- to 50-nm thick floating gate electrodes 22 made of polysilicon or the like are formed via a tunnel gate insulating film 21 made of, e.g., a 4- to 20-nm thick silicon oxide film, oxynitride film, or silicon nitride film.

On the floating gate electrodes 22, an ONO film (a multilayered film made up of a silicon oxide film, silicon nitride film, and silicon oxide film) serving as an interpoly insulating film 23 is stacked such that the thicknesses of the silicon oxide film, silicon nitride film, and silicon oxide film are, e.g., 2 to 10 nm, 5 to 15 nm, and 2 to 10 nm, respectively.

The interpoly insulating film 23 can be, e.g., an Al₂O₃ film or a single-layered silicon oxide film, and the thickness of the film is 5 to 30 nm.

On the interpoly insulating film 23, polysilicon serving as control gate electrodes 24 (a select gate electrode 24 (SG) for a select transistor, and a data selecting line 24 (WL1) and data selecting line 24 (WL2) for semiconductor memory transistors) are formed to have a thickness of 10 to 500 nm.

On this polysilicon, a 10- to 500-nm thick Wsi or W layer is formed as a control gate resistance decreasing metal film 25.

When Wsi is to be used, a metal made of Wsi having an Si/W composition ratio of 2.4 or less is preferred to a metal made of conventionally used Wsi having an Si/W composition ratio of 2.4 or more, because the resistance can be decreased.

More specifically, when the Si/W composition ratio is 2 to 2.15, the resistance can be decreased to be smaller than 70% of the resistance of Wsi having an Si/W composition ratio of 2.4 or more. Accordingly, the resistance can be maintained at a predetermined value or less even when the design rule is reduced by one generation (70 to 80%), i.e., even when the control line width is reduced by one generation while the length of a data control line is held.

Since, therefore, the cell array scale can be increased while the length in the data control line direction is held constant, this is particularly desirable in designing a NAND nonvolatile semiconductor memory having limitations on the package size in the data control line direction.

On the control gate resistance decreasing metal film 25, a 10- to 500-nm thick mask insulating film 26, such as a silicon nitride film or silicon oxynitride film (SiON), which serves as an etching mask material for gate electrode formation is stacked. The control gate resistance decreasing metal film 25 may also be a stacked insulating film of, e.g., a silicon oxide film and silicon nitride film.

The mask insulating film 26 must be oxidation-resistant in order to prevent an oxidizer from oxidizing the control gate resistance decreasing metal film 25 from the upper surface during sidewall oxidation.

In addition, on the side surfaces of the control gate resistance decreasing metal film 25 and the two sides of the upper portions of the side surfaces of the polysilicon film serving as the control gate electrodes 24, a sidewall insulating film 31 made of, e.g., a 2- to 20-nm thick silicon nitride film or silicon oxynitride film is formed.

The sidewall insulating film 31 must be oxidation-resistant in order to prevent an oxidizer from oxidizing the control gate resistance decreasing metal film 25 from the upper surface during sidewall oxidation.

In particular, the sidewall insulating film 31 must be formed before a gate post-oxidation step. To prevent an oxidizer for gate post-oxidation from entering between the sidewall insulating film 31 and control gate resistance decreasing metal film 25, the sidewall insulating film 31 is desirably formed in direct contact with the control gate resistance decreasing metal film 25.

Furthermore, on the sidewalls of the lower portions of the control gate electrodes 24, a sidewall oxide film 42 made of, e.g., a 3- to 20-nm thick silicon oxide film is formed.

Also, on the sidewalls of the floating gate electrodes 22, a sidewall oxide film 41 made of, e.g., a 3- to 20-nm thick silicon oxide film is formed.

The sidewall oxide film 41 is formed by oxidation of the floating gate electrodes 22, and may also be a silicon oxynitride film (SiON) having an oxygen composition larger than that of the sidewall insulating film 31. Note that the sidewall oxide film 42 is separated from the control gate resistance decreasing metal film 25.

An N-type impurity is ion-implanted into the surface portion of the semiconductor substrate 10 by using the gate electrodes as masks, thereby forming N-type impurity diffusion layers 51 serving as source and drain regions. A channel region is positioned between the two N-type impurity diffusion layers 51.

The N-type impurity diffusion layers 51, floating gate electrodes 22, and control gate electrodes 24 form floating gate type nonvolatile EEPROM cells. The gate length of the floating gate electrode 22 is 0.01 to 0.5 μm.

The N-type impurity diffusion layers 51 as source and drain regions are formed at a depth of 10 to 500 nm from the surface of the semiconductor substrate 10, so that the surface concentration of phosphorus, arsenic, or antimony is 10¹⁷ to 10²¹ cm⁻³.

The N-type impurity diffusion layers 51 are shared by adjacent semiconductor memories to realize, e.g., a NAND connection or NOR connection.

Furthermore, an interlayer dielectric film 71 made of, e.g., a silicon oxide film, silicon nitride film, or silicon oxynitride film is buried between the floating gate electrodes 22.

A channel region is formed between the N-type impurity diffusion layers 51 as source and drain regions. In this channel region, the number of conduction carriers can be changed via the gate insulating film 21.

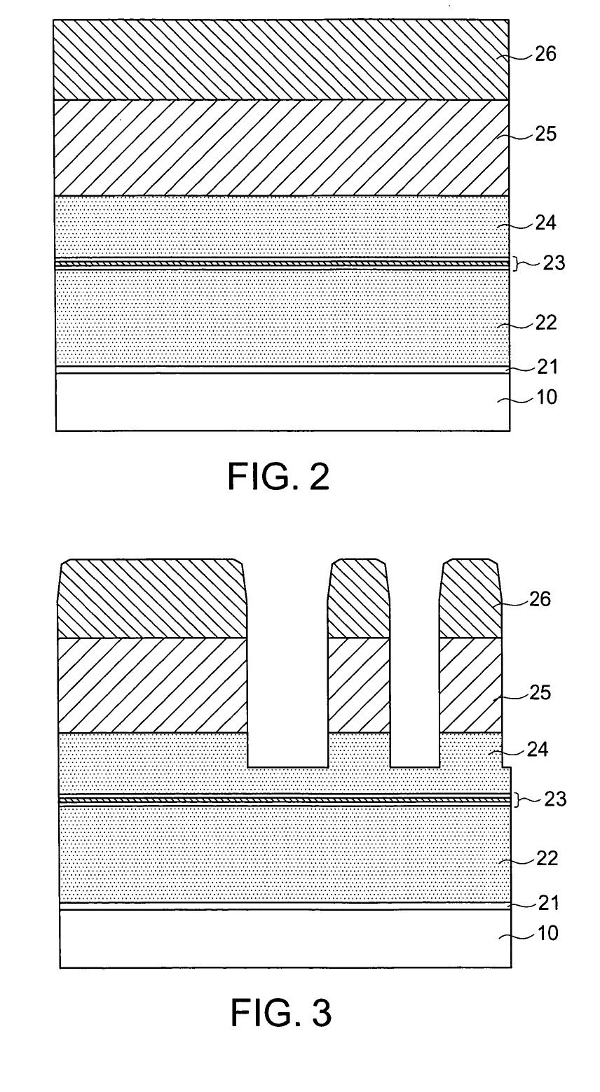

The fabrication steps of this embodiment will be explained below with reference to FIGS. 2 to 8.

On a P-type silicon semiconductor substrate 10 having a boron or indium impurity concentration of 10¹⁴ to 10¹⁹ cm⁻³, a tunnel gate insulating film 21 made of, e.g., a 4- to 20-nm thick silicon oxide film, oxynitride film, or nitride film is formed.

Then, a 10- to 500-nm thick floating gate electrode 22 made of, e.g., polysilicon is formed by LPCVD.

On the floating gate electrode 22, an ONO film (a multilayered film made up of a silicon oxide film, silicon nitride film, and silicon oxide film) serving as an interpoly insulating film 23 is stacked such that the thicknesses of the silicon oxide film, silicon nitride film, and silicon oxide film are, e.g., 2 to 10 nm, 5 to 15 nm, and 2 to 10 nm, respectively. For example, the interpoly insulating film 23 can be an Al₂O₃ film or a single-layered silicon oxide film.

On the interpoly insulating film 23, polysilicon serving as control gate electrodes 24 (a select gate electrode 24 (SG), data selecting line 24 (WL1), and data selecting line 24 (WL2)) are formed to have a thickness of 10 to 500 nm.

On this polysilicon, a 10- to 500-nm thick Wsi or W layer is stacked as a control gate resistance decreasing metal film 25.

On these electrodes, a 50- to 800-nm thick mask insulating film 26, such as a silicon nitride film or silicon oxynitride film, which functions as an etching mask material for gate formation is stacked. As described above, the mask insulating film 26 may also be a stacked insulating film of, e.g., a silicon oxide film and silicon nitride film. In this manner, a stacked structure shown in FIG. 2 is obtained.

Subsequently, as shown in FIG. 3, a resist film patterned by lithography is used as a mask to partially etch away the mask insulating film 26, the control gate resistance decreasing metal film 25, and the control gate electrode 24 made of a polysilicon film or the like, by using an etching technique such as reactive ion etching (to be referred to as RIE hereinafter).

Letting tox2 be the thickness of the sidewall oxide film 42 shown in FIG. 1, the etching depth of the control gate electrode 24 is desirably 4×tox2 or more, in order to prevent bird's beaks of the sidewall oxide film 42 from reaching the control gate resistance decreasing metal film 25.

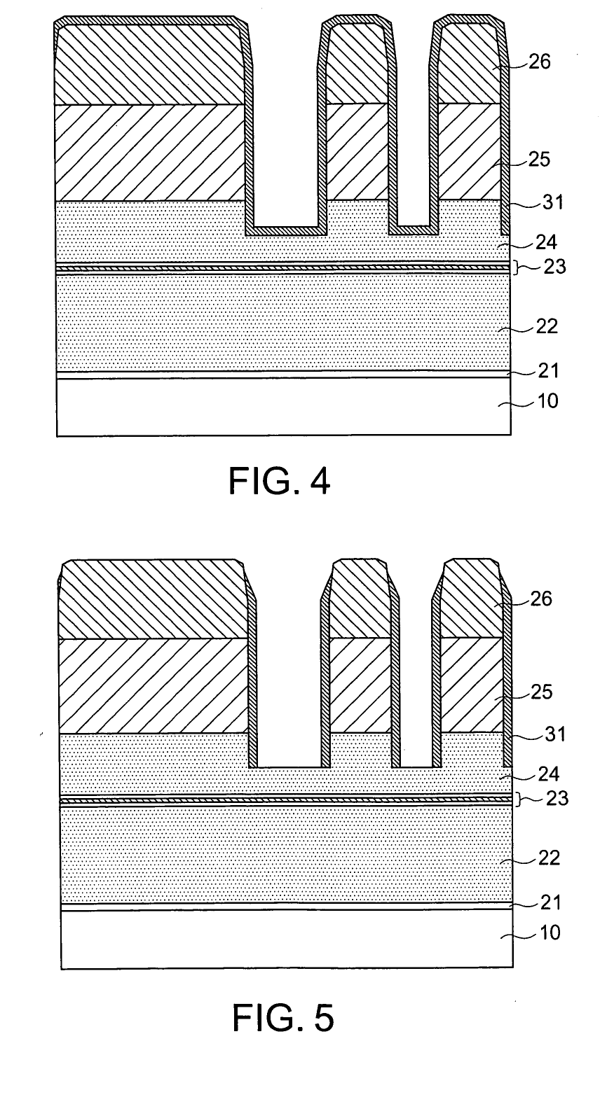

As shown in FIG. 4, a sidewall insulating film 31 made of a 2- to 20-nm thick silicon nitride film or silicon oxynitride film is deposited on the entire surface.

When a silicon nitride film is to be formed, this film is preferably formed in a heating step at 800° C. or less because the temperature is lower than that of a heating step of forming a gate sidewall oxide film later. This silicon nitride film can be any of dichlorosilane-based, tetrachlorosilane-based, and hexachlorodisilane-based silicon nitride films.

Anisotropic etching is then performed such that the sidewall insulating film 31 remains on sheer gate sidewalls and does not remain on the polysilicon upper surfaces of the control gate electrodes 24, thereby obtaining a shape shown in FIG. 5.

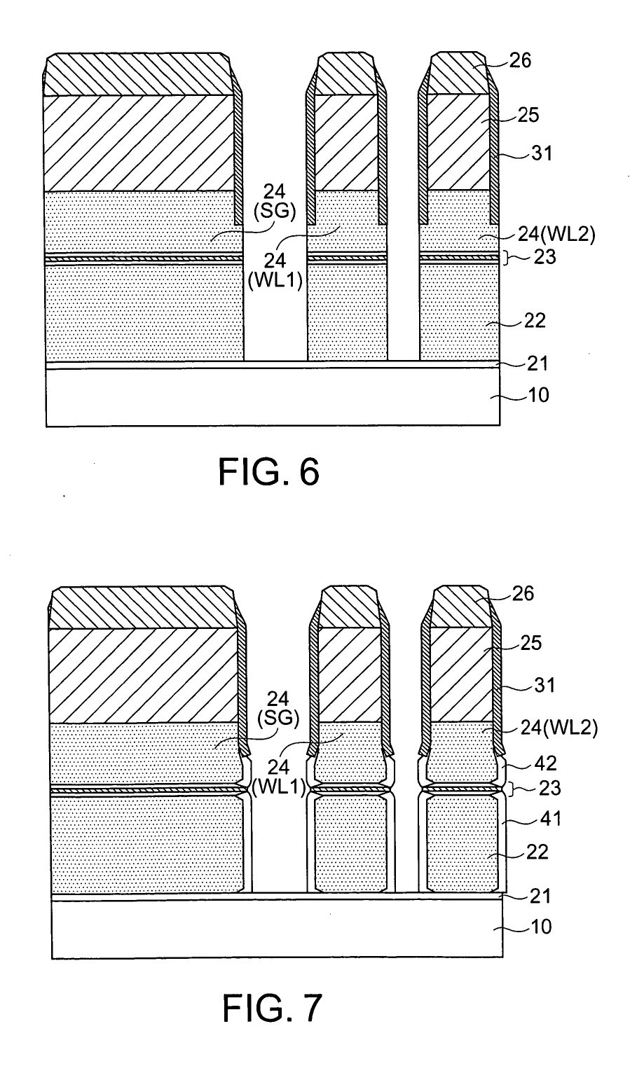

Furthermore, the mask insulating film 26 is used as an etching mask to anisotropically etch the control gate electrodes 24, interpoly insulating film 23, and floating gate electrode 22, thereby obtaining a shape shown in FIG. 6.

After that, to recover etching damage to the tunnel oxide film 21, a post-oxidation process is performed by annealing in an oxidizing ambient.

As shown in FIG. 7, when a gate sidewall post-oxidation process is performed, thin sidewall oxide films 41 and 42 are formed on the side walls of the floating gate electrodes 22 and control gate electrodes 24.

In this oxidation, it is unnecessary to use the W selective oxidation conditions by which the viscosity of the oxide films rises in the conventional device as described previously. That is, it is possible to select oxidation conditions, such as ISSG oxidation or high-temperature oxidation at 1,000° C. or higher, by which the floating gate electrode 22 is not sharply pointed at the contact point between the sidewall oxide film 41 and tunnel oxide film 21 while the viscosity of the oxide films is kept low.

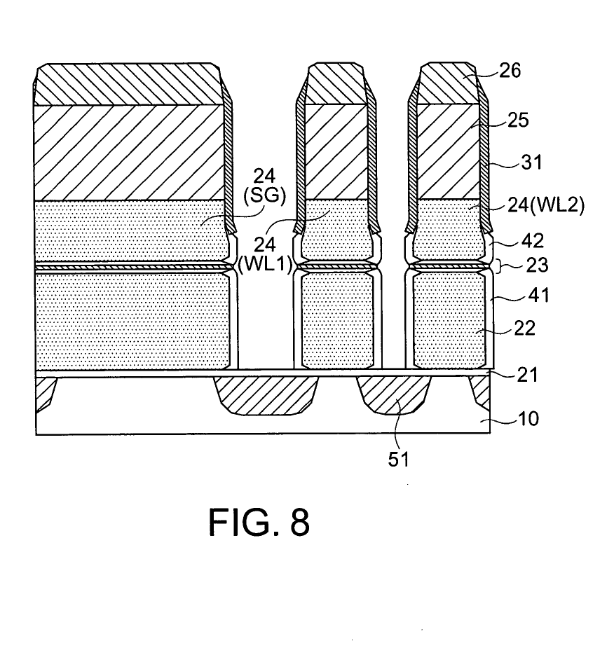

After that, as shown in FIG. 8, N-type impurity diffusion layers 51 serving as source and drain regions are formed by ion implantation or the like of, e.g., phosphorus, arsenic, or antimony, so that the surface concentration is 10¹⁷ to 10²¹ cm⁻³.

Since the metal of the control gate electrodes 24 does not abnormally oxidize, the breakdown voltage between the control gates does not decrease. Also, the impurity diffusion layers 51 can be evenly formed without any influence of shadowing.

Finally, a 50- to 400-nm thick silicon oxide film made of, e.g., TEOS, HTO, BSG, PSG, BPSG, or HDP is deposited as an interlayer dielectric film 71 on the entire surface and buried by anisotropic etching until portions between cells are filled, thereby obtaining the sectional structure shown in FIG. 1.

The following functions and effects are obtained by this embodiment.

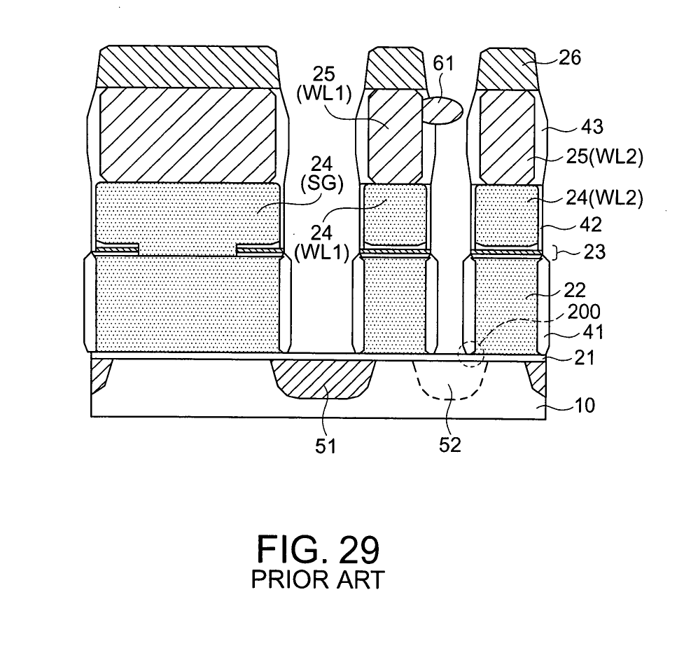

(1) In the gate sidewall oxidation step, the oxidizer does not reach the control gate resistance decreasing metal film 25. Accordingly, no oxide film thicker than the control gate electrode 24 positioned below the control gate resistance decreasing metal film 25, such as the oxide 61 formed on the sidewalls of the control gate resistance decreasing metal film 25 shown in FIG. 29, is formed. Consequently, the normal shape and dimensions as a gate electrode can be maintained.

This reduces the possibility that the metal contained in the control gate resistance decreasing metal film 25 diffuses in an oxidation furnace and causes metal contamination in the gate sidewall oxidation step. Accordingly, the junction leak characteristics on the same wafer can be improved more than the conventional methods.

Also, no seam is formed in the interlayer dielectric film unlike in the conventional devices, so good burying characteristics can be obtained. Therefore, the controllability of the etching depth can be improved when contacts are formed later in the dielectric film 71 shown in FIG. 1.

Furthermore, when a plurality of semiconductor memories are to be formed adjacent to each other in the direction perpendicular to the paper of FIG. 1, no conductor for contact electrode formation enters between the adjacent semiconductor memories, so the insulation properties between these memories can be well maintained.

In particular, those side surfaces of the sidewall oxide film 41, which are not in contact with the floating gate electrode 22 extend more than those side surfaces of the sidewall insulating film 31, which are not in contact with the side surfaces of the control gate resistance decreasing metal film 25. Consequently, as shown in FIG. 1, a forward tapered shape is formed when the interlayer dielectric film 71 is buried, unlike in the conventional devices. Since this eliminates seams formed in the conventional devices, the reliability can be further improved.

(2) In the gate sidewall oxidation step, both the control gate electrode 24 in contact with the upper portions of the sidewalls of the interpoly insulating film 23 and the floating gate electrode 22 in contact with the lower portions of the sidewalls of the interpoly insulating film 23 oxidize to form bird's beaks at the upper and lower edges of the sidewalls of the interpoly insulating film 23, thereby increasing the film thickness.

Accordingly, even if defects are formed in the interpoly insulating film 23 in the etching step for gate electrode formation, the electric field can be reduced by the increase in film thickness. As a consequence, a semiconductor memory having higher reliability can be realized.

In particular, those lower portions of the sidewalls of the floating gate electrode 22, which are in contact with the interpoly insulating film 23 oxidize to form bird's beaks on the interpoly insulating film 23, and the thickness of the edges of these portions increase. Therefore, unlike in the technique disclosed in patent reference 1 mentioned earlier, damage is recovered even if defects are formed in the interpoly insulating film 23 in the etching step of patterning the gate electrode shape. In addition, field concentration is reduced by increasing the thickness of the interpoly insulating film 23, so the reliability can be improved.

(3) Unlike in the conventional devices, the control gate resistance decreasing metal film 25 does not abnormally oxidize, and the thickness of the sidewall oxide film 41 can be increased. This makes it possible to prevent electrons from being discharged from the floating gate electrode 22 through the sidewall oxide film 41.

Consequently, the holding characteristics of electrons stored in the floating gate electrode 22 can be improved.

(4) As described above, the phenomenon in which the floating gate electrode 22 is sharply pointed after the oxidation step can be prevented. This prevents field concentration to a sharp-pointed portion during erase in which electrons are extracted from the floating gate electrode 22. Accordingly, electrons can be discharged more evenly from the floating gate electrode 22 to the semiconductor substrate 10 or impurity diffusion layers 51.

As a consequence, electrons are more evenly discharged to the edges and channel region of the floating gate electrode 22. Therefore, no deterioration occurs even when write and erase are repeated by using the device as a flash semiconductor memory, so the reliability can be improved.

(5) The conventional gate sidewall post-oxidation step has the problem that the oxidizer comes in direct contact with the control gate resistance decreasing metal film 25, and the control gate resistance decreasing metal film 25 abnormally oxidizes. In this embodiment, however, the side surfaces of the control gate resistance decreasing metal film 25 are covered with the oxidation-resistant sidewall insulating film 31, and the upper surface of the control gate resistance decreasing metal film 25 is covered with the mask insulating film 26. Therefore, the problem of abnormal oxidation can be avoided because there is no contact with the oxidizer.

Also, the gate length of the floating gate electrode 22 and tunnel insulating film 21 increases by an amount twice the thickness of the sidewall insulating film 31. This suppresses the short channel effect.

(6) In this embodiment, the lower portion of the control gate electrode 24, and the interpoly insulating film 23 and floating gate electrode 22 are simultaneously processed. This decreases the dimensional differences in the gate length direction.

Accordingly, the ratio of the capacitance of the interpoly insulating film 23 to the capacitance of the tunnel insulating film 21 can be held high.

(7) It is possible to select oxidation conditions by which the shape of the floating gate electrode 22 at the contact point between the sidewall oxide film 41 and tunnel oxide film 21 is not sharply pointed.

Also, since the thickness of the sidewall oxide film 41 can be made larger than in the conventional devices without any abnormal oxidation, no electrons are easily discharged from the floating gate electrode 22 through the sidewall oxide film 41. As a consequence, the holding characteristics of electrons stored in the floating gate electrode 22 can be improved.

Furthermore, the floating gate electrode 22 can be prevented from being sharply pointed. Therefore, during erase in which electrons are extracted from the floating gate electrode 22, field concentration to a sharp-pointed portion can be prevented. This makes it possible to more evenly discharge electrons from the floating gate electrode 22 to the semiconductor substrate 10 or impurity diffusion layers 51.

Consequently, electrons are more evenly discharged to the edges and channel region of the floating gate electrode 22. Accordingly, no deterioration occurs even when write and erase are repeated by using the device as a flash semiconductor memory, so the reliability can be improved.

(B) Second Embodiment

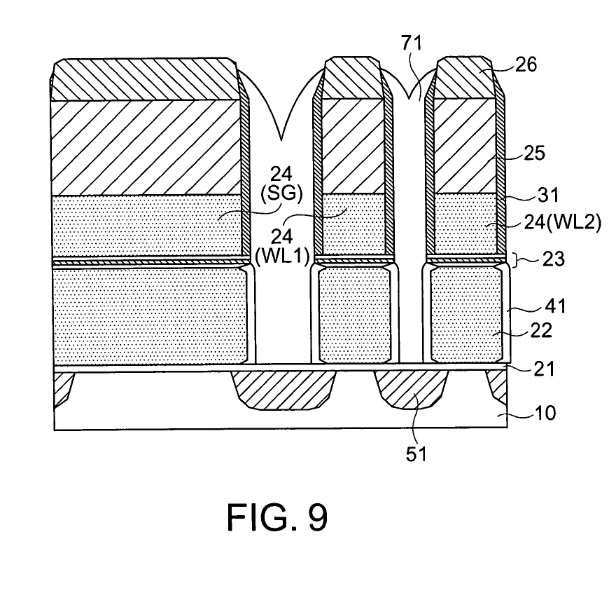

FIG. 9 shows the structure of a nonvolatile semiconductor memory according to the second embodiment of the present invention.

This embodiment differs from the first embodiment in that a sidewall insulating film 31 is so formed as to reach an interpoly insulating film 23. The same reference numerals as in the first embodiment denote the same parts, and an explanation thereof will be omitted.

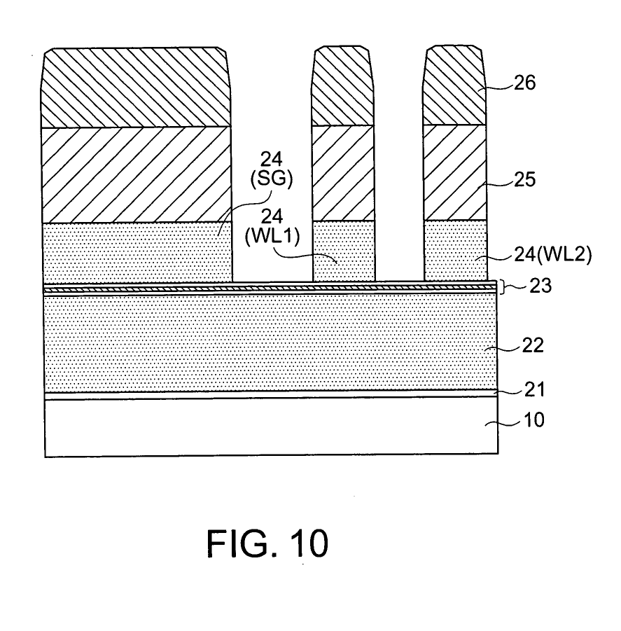

FIGS. 10 to 15 illustrate device sections in different fabrication steps of this embodiment.

First, in the same manner as in the first embodiment, a tunnel gate insulating film 21, floating gate electrode 22, interpoly insulating film 23, control gate electrode 24 (a selecting gate electrode 24 (SG), data selecting line 24 (WL1), and data selecting line 24 (WL2)), control gate resistance decreasing metal film 25, and mask insulating film 26 are stacked on a P-type semiconductor substrate 10, thereby obtaining the structure shown in FIG. 2.

Subsequently, as shown in FIG. 10, a resist patterned by lithography is used as a mask to pattern the mask insulating film 26, control gate resistance decreasing metal film 25, and control gate electrode 24 until the interpoly insulating film 23 is reached, by using an etching technique such as RIE.

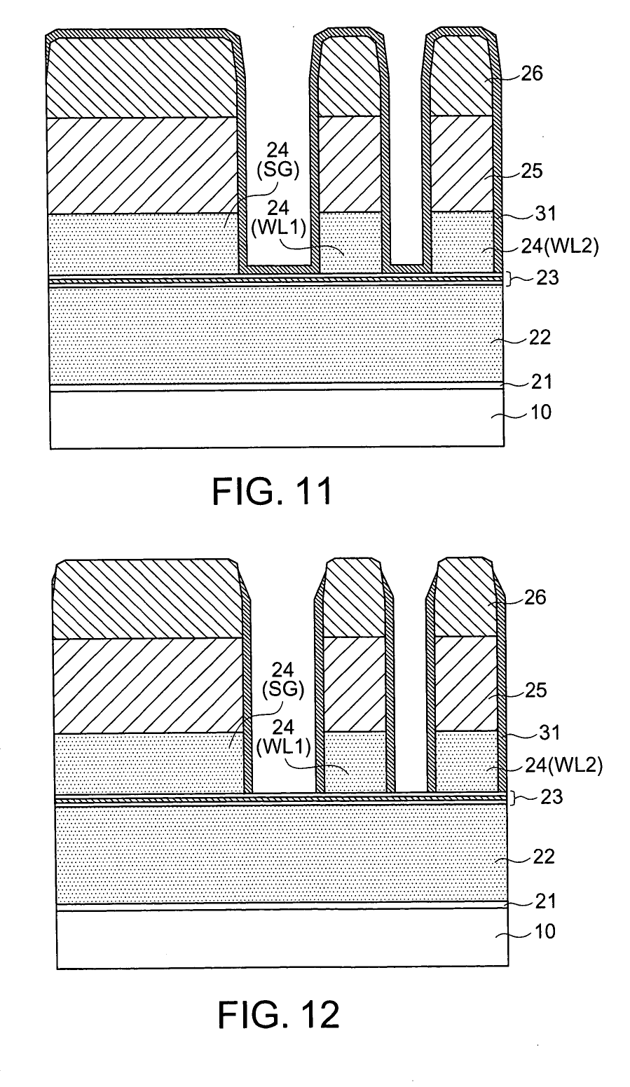

As shown in FIG. 11, a sidewall insulating film 31 made of a 2- to 20-nm thick silicon nitride film or silicon oxynitride film is deposited on the entire surface.

Note that the silicon nitride film to be deposited is desirably formed in a heating step at 800° C. or less because the temperature is lower than that of a maximum heating step of forming a gate sidewall oxide film later. This silicon nitride film can be a dichlorosilane-based silicon nitride film, or a tetrachlorosilane-based or hexachlorodisilane-based silicon nitride film.

Anisotropic etching is then performed such that the sidewall insulating film 31 remains on sheer gate sidewalls and does not remain on the upper surface of the floating gate electrode 22, thereby obtaining a shape shown in FIG. 12.

In this step, the interpoly insulating film 23 and sidewall insulating film 31 can be patterned with high controllability, as shown in FIG. 12, by using insulating film etching conditions having a selective ratio to polysilicon.

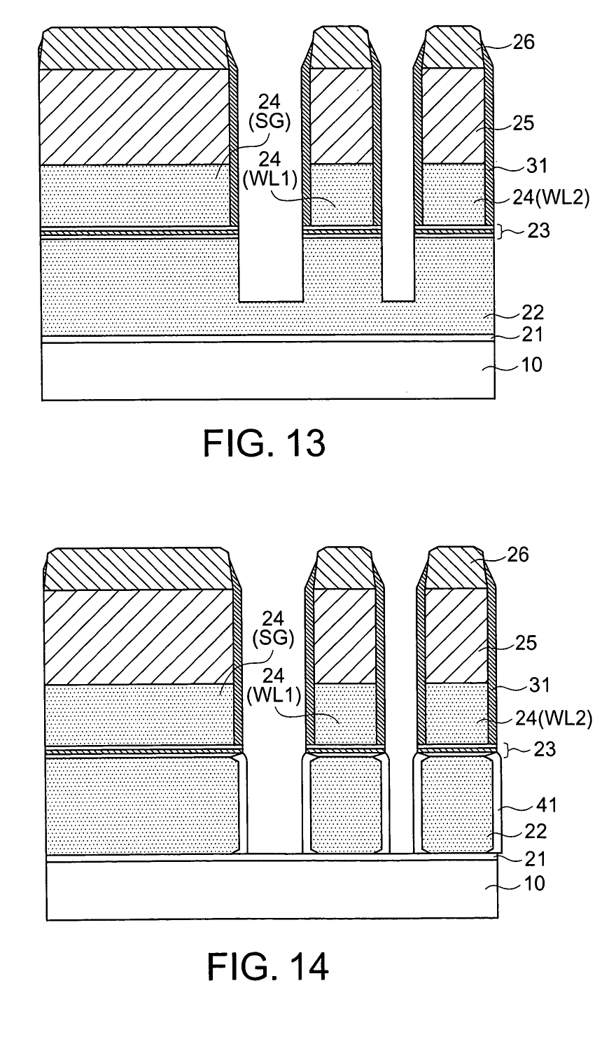

Furthermore, the mask insulating film 26 and sidewall insulating film 31 are used as etching masks to pattern the floating gate electrode 22 by anisotropic etching, thereby obtaining a shape shown in FIG. 13.

After that, to recover etching damage to the tunnel oxide film 21, a post-oxidation process is performed by annealing in an oxidizing ambient.

Also, as shown in FIG. 14, on the side walls of the floating gate electrodes 22 having undergone the gate sidewall post-oxidation process, the oxidizer and polysilicon react with each other to form a thin sidewall oxide film 41.

In this oxidation, as in the first embodiment described above, it is possible to select oxidation conditions, such as ISSG oxidation or high-temperature oxidation at 1,000° C. or higher, by which the floating gate electrode 22 is not sharply pointed at the contact point between the sidewall oxide film 41 and tunnel oxide film 21 while the viscosity of the oxide films is kept low.

The sidewall oxide film 41 may also be a silicon oxynitride film formed by oxidation of the floating gate electrode 22 and having an oxygen composition larger than that of the sidewall insulating film 31.

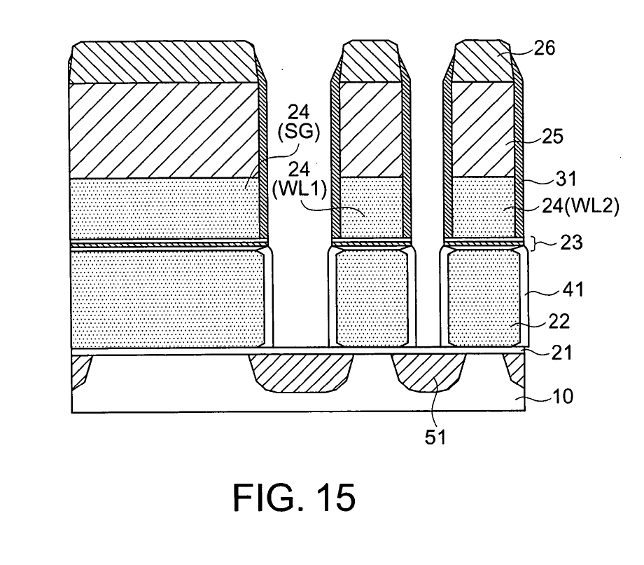

After that, N-type impurity diffusion layers 51 serving as source and drain regions are formed by ion implantation of, e.g., phosphorus, arsenic, or antimony, so that the surface concentration is 10¹⁷ to 10²¹ cm ⁻³, thereby obtaining a structure shown in FIG. 15.

Since the control gate resistance decreasing metal film 25 does not abnormally oxidize, the breakdown voltage between the control gates does not decrease, and the impurity diffusion layers 51 can be evenly formed without any influence of shadowing.

Finally, a 50- to 400-nm thick silicon oxide film made of, e.g., TEOS, HTO, BSG, PSG, BPSG, or HDP is deposited on the entire surface and anisotropically etched until portions between cells are filled, thereby obtaining the sectional structure shown in FIG. 9.

This embodiment has the following characteristic features in addition to characteristic features (1), (3) to (5), and (7) described in the first embodiment.

(8) In the etching step shown in FIG. 10, the polysilicon etching conditions having a selective ratio to the interpoly insulating film 23 are used. So, etching can be controlled to stop at the interpoly insulating film 23.

Accordingly, in the etching step shown in FIG. 13 performed after that, the etching amount can be controlled independently of variations in film thickness of the control gate electrodes 24. This prevents an over etching phenomenon.

This makes it possible to make the depth of the impurity diffusion layers 51 more constant, and realize a more uniform semiconductor memory.

(9) Sine the thickness of the sidewalls of the control gate electrodes 24 does not increase by oxidation, it is possible to obtain a shape by which the burying properties of the interlayer dielectric film 71 are superior even in the interpoly insulating film 23.

This embodiment also has the following characteristic feature compared to (2) described in the first embodiment.

(2′) In the gate sidewall oxidation step, the floating gate electrode 22 in contact with the sidewalls of the interpoly insulating film 23 oxidizes to form bird's beaks on the lower side (near the floating gate electrode 22) of the sidewalls of the interpoly insulating film 23, thereby increasing the film thickness.

Accordingly, although the structure is different from the first embodiment in which bird's beaks are formed at both the upper and lower edges of the interpoly insulating film 23, the electric field can be reduced by the increase in film thickness on the lower side. As a consequence, a semiconductor memory having higher reliability can be realized.

Furthermore, although the thickness of the interpoly insulating film 23 is smaller than that in the first embodiment, the smaller this film thickness, the better the write characteristics. In this embodiment, therefore, it is possible to improve the reliability and ensure the write characteristics at the same time by increasing the film thickness of only the lower portions of the sidewalls of the interpoly insulating film 23.

(C) Third Embodiment

A nonvolatile semiconductor memory according to the third embodiment of the present invention will be described below.

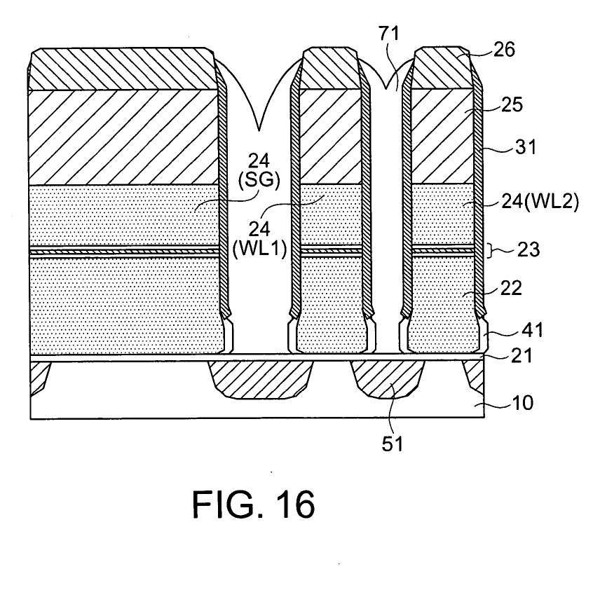

As shown in FIG. 16, the structure of this embodiment differs from the first and second embodiments in that a sidewall insulating film 31 is so formed as to reach middle portions of floating gate electrodes 22. The same reference numerals as in the first and second embodiments denote the same parts, and an explanation thereof will be omitted.

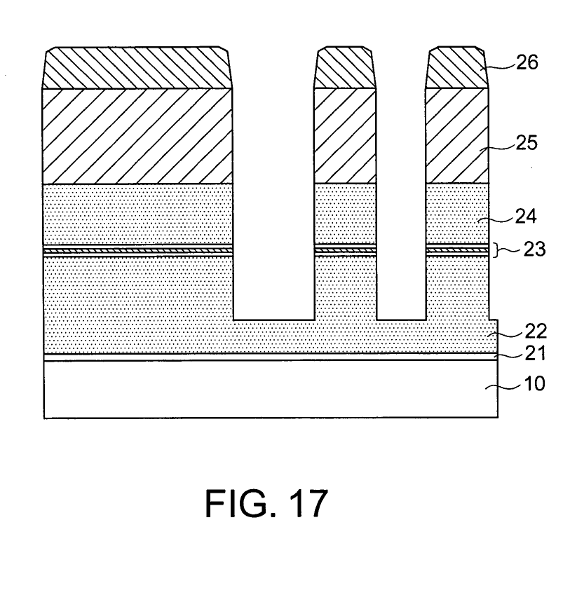

A method of fabricating the nonvolatile semiconductor memory according to this embodiment will be described below with reference to FIGS. 17 to 22.

First, in the same manner as in the first and second embodiments, a tunnel gate insulating film 21, floating gate electrode 22, interpoly insulating film 23, control gate electrode 24 (a selecting gate electrode 24 (SG), data selecting line 24 (WL1), and data selecting line 24 (WL2)), control gate resistance decreasing metal film 25, and mask insulating film 26 are stacked on a P-type semiconductor substrate 10, thereby obtaining the structure shown in FIG. 2.

As shown in FIG. 17, a resist patterned by lithography is used as a mask to partially etch away the mask insulating film 26, control gate resistance decreasing metal film 25, control gate electrode 24, the interpoly insulating film 23, and floating gate electrode 22 by using an etching technique such as RIE.

The etching depth of the floating gate electrode 22 can be set with high controllability by stopping the etching on an element isolation film (not shown) having a surface within the range of the film thickness of the floating gate electrode 22, or on the upper surface of a gate oxide film (not shown) of a peripheral transistor whose film thickness is increased so as to be able to apply a high voltage.

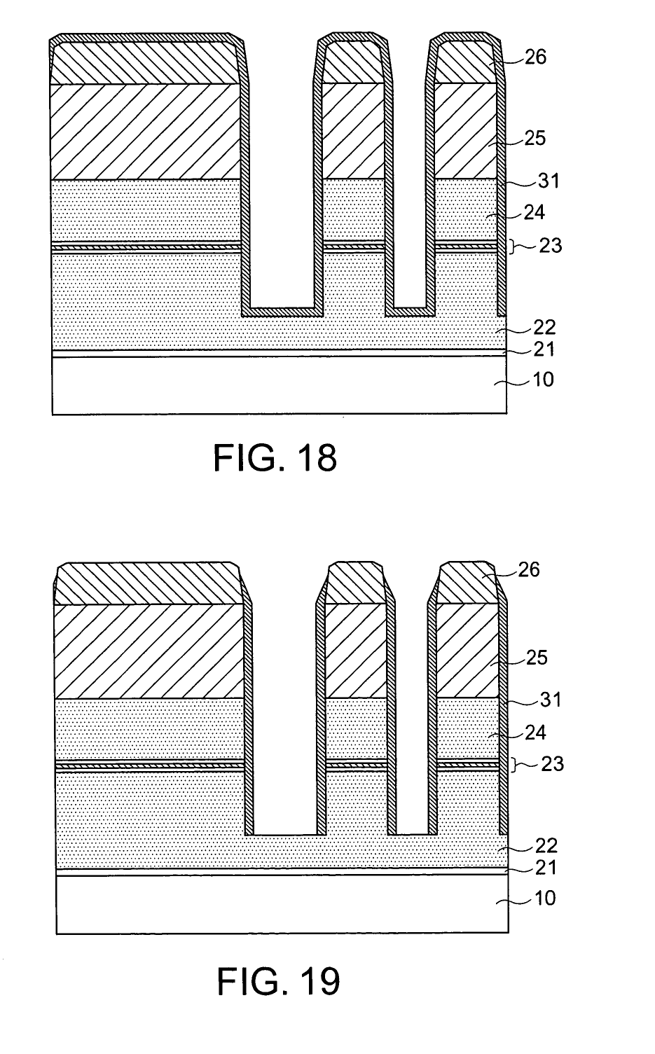

As shown in FIG. 18, a sidewall insulating film 31 made of a 2- to 20-nm thick silicon nitride film or silicon oxynitride film is deposited on the entire surface.

As in the first and second embodiments, the silicon nitride film to be deposited is desirably formed in a heating step at 800° C. or less. This silicon nitride film can be a dichlorosilane-based silicon nitride film, or a tetrachlorosilane-based or hexachlorodisilane-based silicon nitride film.

Anisotropic etching is then performed such that the sidewall insulating film 31 remains on sheer gate sidewalls and does not remain on the polysilicon upper surface of the floating gate electrode 22, thereby obtaining a shape shown in FIG. 19.

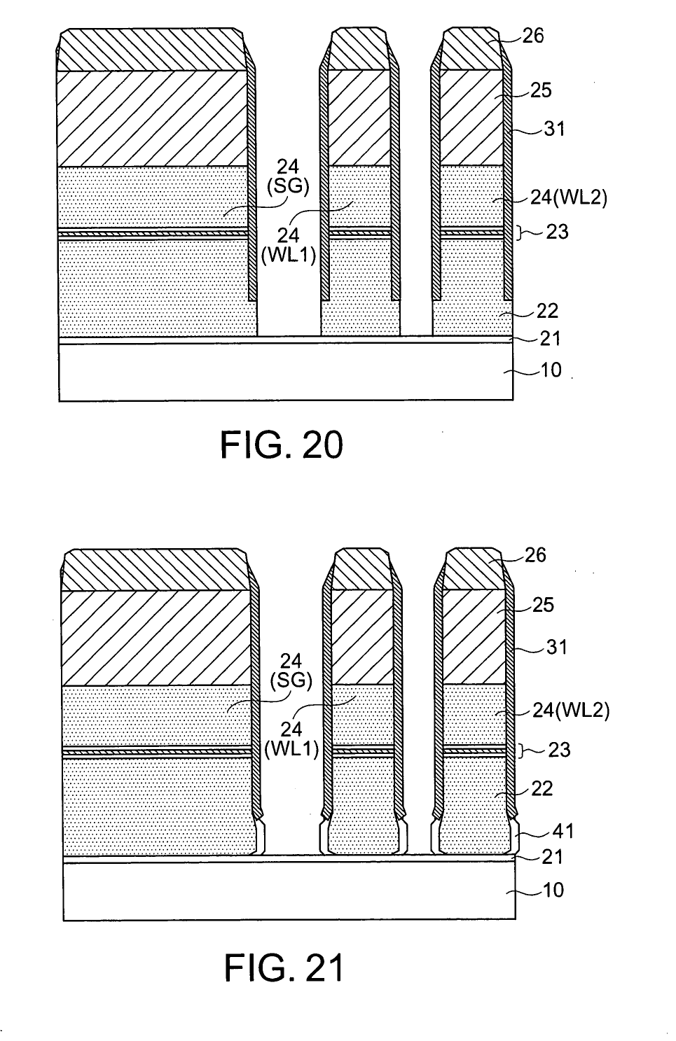

Furthermore, the mask insulating film 26 is used as an etching mask to process the floating gate electrode 22 by anisotropic etching, thereby obtaining a shape shown in FIG. 20. To recover etching damage to the tunnel oxide film 21, a post-oxidation process is performed by annealing in an oxidizing ambient.

Also, as shown in FIG. 21, a post-oxidation process is performed to allow the oxidizer and polysilicon to react with each other, thereby forming a thin sidewall oxide film 41 made of a silicon oxide film on the side walls of the floating gate electrodes 22.

In this oxidation, as in the first and second embodiments described above, it is possible to select oxidation conditions, such as ISSG oxidation or high-temperature oxidation at 1,000° C. or higher, by which the floating gate electrode 22 is not sharply pointed at the contact point between the sidewall oxide film 41 and tunnel oxide film 21 while the viscosity of the oxide films is kept low.

The sidewall oxide film 41 may also be a silicon oxynitride film formed by oxidation of the floating gate electrodes 22 and having an oxygen composition larger than that of the sidewall insulating film 31.

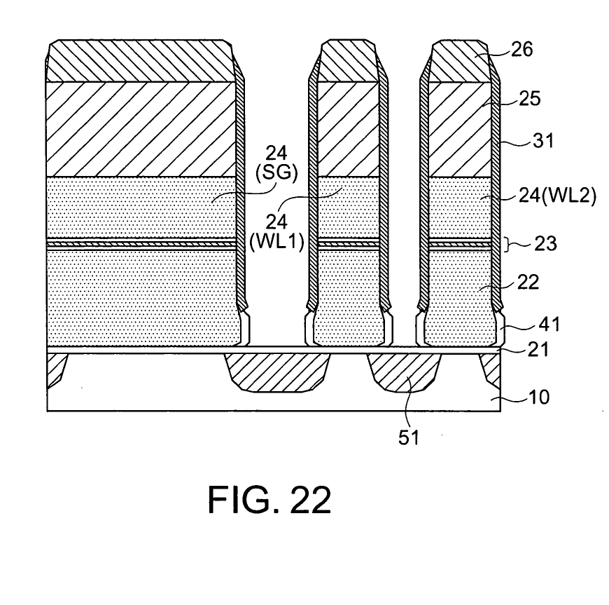

After that, N-type impurity diffusion layers 51 serving as source and drain regions are formed by ion-implanting an impurity such as phosphorus, arsenic, or antimony so that the surface concentration is 10¹⁷ to 10²¹ cm⁻³, thereby obtaining a structure shown in FIG. 22.

Since the metal of the control gate electrodes 24 does not abnormally oxidize, the breakdown voltage between the control gates does not decrease, and the impurity diffusion layers 51 can be evenly formed without any influence of shadowing.

Finally, a 50- to 400-nm thick silicon oxide film made of, e.g., TEOS, HTO, BSG, PSG, BPSG, or HDP is deposited on the entire surface and anisotropically etched until portions between cells are filled, thereby obtaining the sectional structure shown in FIG. 16.

This embodiment has the following characteristic features in addition to characteristic features (1), (3) to (5), and (7) described in the first embodiment, and characteristic feature (9) described in the second embodiment.

(10) The sidewalls of the interpoly insulating film 23 are covered with the sidewall insulating film 31, and hence can prevent permeation of hydronium ion or hydrogen because these sidewalls are not exposed to the gate post-oxidation ambient. Therefore, unlike in the technique disclosed in patent reference 1, an increase in leakage current can be prevented even when, e.g., an Si film is contained in the interpoly insulating film 23. Also, even when a high-dielectric film such as an Al₂O₃ film is used, a good insulating film can be formed without increasing the leakage current.

This embodiment also has the following characteristic feature compared to (2) described in the first embodiment and (2′) in the second embodiment.

In the gate sidewall oxidation step, those portions of the control gate electrodes 24 and floating gate electrodes 22, which are in contact with the sidewalls of the interpoly insulating film 23 do not oxidize because they are covered with the sidewall insulating film 31.

Accordingly, no bird's beaks are formed at the upper and lower edges of the sidewalls of the interpoly insulating film 23, so the film thickness does not increase. Unlike in the first and second embodiments, therefore, field concentration cannot be reduced because the thickness of the interpoly insulating film 23 does not increase.

Since, however, the thickness of the interpoly insulating film 23 does not increase, this embodiment is superior in write characteristics.

(11) The sidewalls of the interpoly insulating film 23 are not exposed to the oxidizing ambient in the gate electrode post-oxidation step, so no bird's beaks are formed on the sidewalls of the interpoly insulating film 23. Accordingly, the capacitance ratio represented by C2/(C1+C2) increases, and the program characteristics improve. C1 indicates the capacitance of the tunnel oxide film 21, and C2 indicates the capacitance of the interpoly insulating film 23.

(D) Fourth Embodiment

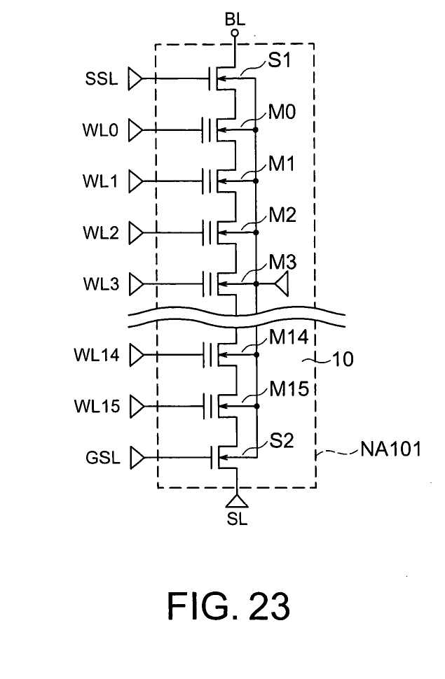

FIG. 23 shows the circuit configuration of a nonvolatile semiconductor memory according to the fourth embodiment of the present invention. In this embodiment, the semiconductor memory structure according to the first embodiment is applied to a NAND cell array.

The same reference numerals as in the first embodiment denote the same parts, and an explanation thereof will be omitted.

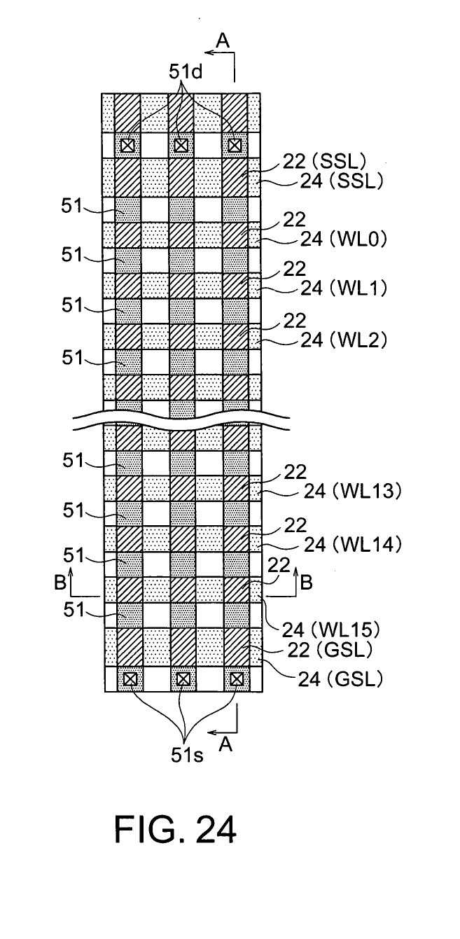

FIG. 23 shows an equivalent circuit of a NAND cell block NA101. FIG. 24 shows the planar arrangement of elements. FIG. 24 shows a structure in which three NAND cell blocks NA101 shown in FIG. 23 are juxtaposed. To clearly show the cell structure in particular, a planar arrangement below control gat electrodes 24 is shown in FIG. 24.

In the NAND cell block NA101, nonvolatile semiconductor memories M0 to M15 each of which is a MOS transistor having a floating gate electrode 22 are connected in series. One end of the series circuit is connected to a data transfer line BL via a select transistor S1. The other end of the series circuit is connected to a common source line SL via a select transistor S2.

The transistors M0 to M15, S1, and S2 are formed on a P-type semiconductor substrate 10 (P-type well).

The control electrodes of the semiconductor memories M0 to M15 are connected to data selecting lines WL0 to WL15, respectively.

Also, to select one of the plurality of NAND semiconductor memory blocks NA101 arranged along the data transfer line BL and to connect the selected semiconductor memory block to the data transfer line BL, the control electrode of the select transistor S1 is connected to a block selecting line SSL. The control electrode of the select transistor S2 is connected to a block selecting line GSL.

In this embodiment, the block selecting lines SSL and GSL are connected between other cells (not shown) adjacent in the horizontal direction of the paper by the same conductor layer as the floating gate electrodes 22 of the data selecting lines WL0 to WL15 of the semiconductor memories M0 to M15.

The semiconductor memory block NA101 need only have at least one block selecting line SSL and at least one block selecting line GSL. The block selecting lines SSL and GSL are desirably formed in the same direction as the data selecting lines WL0 to WL15 in order to increase the density.

In this embodiment, 16=2⁴ semiconductor memories are connected to the semiconductor memory block NA101. However, the number of semiconductor memories connected to the data transfer line BL and data selecting lines WL0 to WL15 need only be a plural number. This number is desirably 2ⁿ (n is a positive integer) in order to perform address decoding.

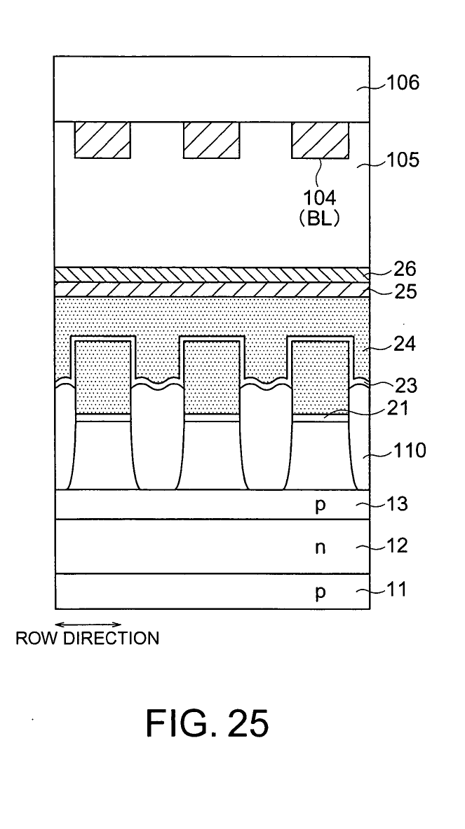

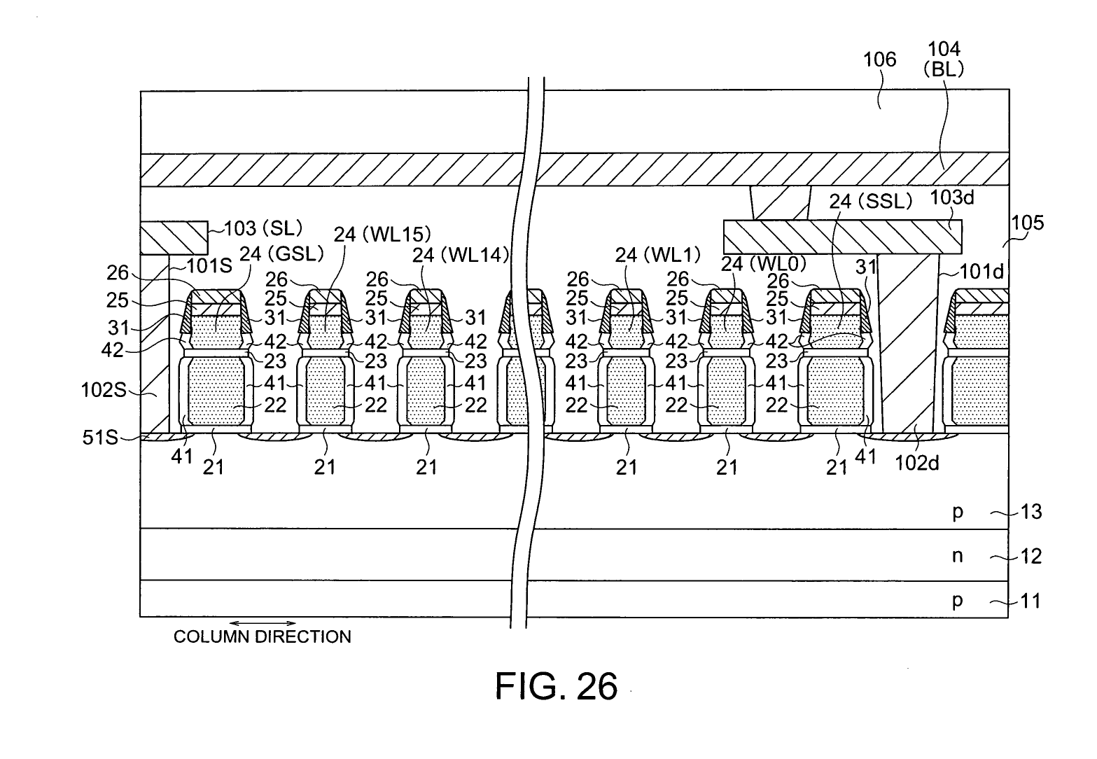

FIG. 25 shows a longitudinal sectional structure taken along a line B-B in FIG. 24. FIG. 26 shows a longitudinal sectional structure taken along a line A-A in FIG. 24. FIG. 25 shows the longitudinal sectional structure of the semiconductor memory.

Referring to FIGS. 24, 25, and 26, on a P-type semiconductor substrate 13 having, e.g., a boron impurity concentration of 10¹⁴ to 10¹⁹ cm⁻³, 10- to 500-nm thick floating gate electrodes 22, 22 (SSL), and 22 (GSL) made of polysilicon doped with 10¹⁸ to 10²¹ cm⁻³ of, e.g., phosphorus or arsenic are formed via tunnel gate insulating films 21, 21 (SSL), and 21 (GSL) made of, e.g., a 4- to 20-nm thick silicon oxide film or oxynitride film.

The floating gate electrodes 22 are formed in self-alignment with the P-type semiconductor region 13 on a region where an element isolation insulating film 110 made of, e.g., a silicon oxide film is not formed.

For example, the element isolation insulating film 110 can be formed by depositing the tunnel gate insulating film 21 and floating gate electrode 22 on the entire surface of the semiconductor region 13, and patterning them until they reach the semiconductor region 13, e.g., to a depth of 0.05 to 0.5 μm by etching, thereby burying the insulating film.

Since the tunnel gate insulating film 21 and floating gate electrode 22 can be formed on the entire plane surface having no steps as described above, the uniformity further improves, and film formation can be performed with good characteristics.

On top of the resulting structure, 10- to 500-nm thick control gate electrodes 24 made of polysilicon doped with 10¹⁷ to 10²¹ cm⁻³ of an impurity such as phosphorous, arsenic, or boron, a stacked structure of Wsi and polysilicon, or a stacked structure of W and polysilicon are formed via an interpoly insulating film 23 made of a 5- to 35-nm thick silicon oxide film, oxynitride film, or silicon oxide film/silicon nitride film/silicon oxide film.

As shown in FIG. 24, the control gate electrodes 24 are formed to the block boundaries in the horizontal direction of the paper so as to be interconnected between the adjacent semiconductor memory blocks, thereby forming the data selecting lines WL0 to WL15.

Note that it is desirable to apply a voltage to the P-type semiconductor region 13 by an N-type semiconductor region 12 independently of a P-type semiconductor substrate 11, in order to reduce the boosting circuit load during erase and suppress the power consumption.

In the gate shape of this embodiment, the sidewalls of the P-type semiconductor region 13 are covered with the element isolation insulating film 110. Therefore, these sidewalls are not exposed by etching before the floating gate electrodes 22 are formed. This prevents the floating gate electrodes 22 from being positioned below the semiconductor region 13.

Accordingly, in the boundary between the semiconductor region 13 and element isolation insulating film 110, it is possible to prevent the concentration of a gate electric field or the formation of a parasitic transistor having a decreased threshold value.

Furthermore, a phenomenon in which a write threshold value is decreased by field concentration, i.e., a so-called sidewalk phenomenon hardly occurs, so transistors having higher reliability can be formed.

Also, as in the first embodiment, as shown in FIG. 26, the side walls of a mask insulating film 26 and control gate resistance decreasing metal film 25 and the side walls of the upper portion of the control gate electrode 24 are covered with a sidewall insulating film 31 made of, e.g., a 2- to 20-nm thick silicon nitride film or silicon oxynitride film.

Additionally, a sidewall insulating film 42 made of a silicon oxide film is formed on the sidewalls of the lower portion of the control gate electrode 24, a sidewall insulating film 41 made of a silicon oxide film is formed on the sidewalls of the floating gate electrode 22, and N-type impurity diffusion layers 51 serving as source and drain regions are formed.

The impurity diffusion layers 51, floating gate electrode 22, and control gate electrode 24 form a floating gate type EEPROM cell in which a charge amount stored in the floating gate electrode 22 is used as an information amount. The gate length is 0.01 to 0.5 μm.

Note that this semiconductor memory structure is the same as the first embodiment describe earlier, so an explanation thereof will be omitted.

The N-type impurity diffusion layers 51 are formed at a depth of 10 to 500 nm so that the surface concentration of, e.g., phosphorus, arsenic, or antimony is 10^{17 to} 10²¹ to cm⁻³. The N-type impurity diffusion layers 51 are shared by adjacent semiconductor memories to realize a NAND connection.

The floating gate electrodes 22 (SSL) and 22 (GSL) are gate electrodes connected to the block selecting lines SSL and GSL, respectively, and formed by the same layer as the floating gate electrode of the floating gate type EEPROM.

The gate length of the floating gate electrodes 22 (SSL) and 22 (GSL) is longer than that of the semiconductor memory gate electrode, e.g., 0.02 to 1 μm. This makes it possible to increase the on/off ratio of the state in which a block is selected to the state in which no block is selected, and to prevent write errors and read errors.

Also, N-type impurity diffusion layers 51d formed on one side of the control gate electrode 24 (SSL) is connected to data transfer lines 104 (BL) made of, e.g., W, Wsi, Ti, TiN, or Al via contacts 102d formed in contact holes 101d.

Although not shown in FIG. 24, data transfer lines 104 (BL) are formed to the block boundaries along the vertical direction of the paper of FIG. 24, so as to be connected to the adjacent semiconductor memory blocks.

On the other hand, N-type impurity diffusion layers 51S formed on one side of the control gate electrode 24 (GSL) are connected to the source line SL (not shown) via contacts 102S formed in contact holes 101S.

Although not shown in FIG. 24, the source line SL is formed to the block boundaries along the horizontal direction of the paper of FIG. 24, so as to be connected between the adjacent semiconductor memory blocks. The source line SL may also be obtained by forming the N-type impurity diffusion layers 51S to the block boundaries in the horizontal direction of the paper.

The contacts 102d for the data transfer lines BL and the contacts 102S for the source line SL are conductor regions obtained by filling the contact holes 101d and 101S with N- or P-doped polysilicon, W, Wsi, Al, TiN, or Ti. Portions between the source line SL, data transfer lines BL, and transistors are filled with an interlayer insulating film 105 made of, e.g., a silicon oxide film or silicon nitride film.

On the data transfer lines BL, an insulating film protective layer 106 made of, e.g., a silicon oxide film, silicon nitride film, or polyimide is formed. Although not shown, upper interconnections made of, e.g., W, Al, or Cu are also formed.

This embodiment has the following characteristic features in addition to the characteristic features of the first embodiment.

(12) In this embodiment, data of a plurality of cells can be simultaneously erased by tunnel injection from the common P-type semiconductor region 13. Therefore, multiple bits can be simultaneously erased at high speed while the power consumption during erase is suppressed.

Also, this embodiment has the effect of increasing the width of the floating gate electrode 22 by the formation of the sidewall insulating film 31. This achieves the following effects.

(13) As shown in FIGS. 6, 14, and 20, the width of the floating gate electrode 22 can be increased by an amount twice the thickness of the sidewall insulating film 31 with respect to the processing dimensions of the mask insulating film 26 which are determined by the lithography accuracy.

Especially in a NAND EEPROM, the impurity diffusion layers of the memory cell transistors M0 to M15 are connected in series as they are shared between one impurity diffusion layer of the select transistor S1 having the other impurity diffusion layer connected to the bit line BL and one impurity diffusion layer of the select transistor S2 having the other impurity diffusion layer connected to the source line SL. Therefore, the diffusion layer resistance functions as a parasitic resistance. This reduces the electric current on the bit line BL during read, and thereby prolongs the read time.

In this embodiment, the length of the impurity diffusion layer decreases by the increase in width of the gate electrode, and the parasitic resistance in the impurity diffusion layer reduces. As a consequence, the read electric current increases, and this increases the speed of the read operation.

Also, in a NAND EEPROM, a leakage current from a NAND block or memory cell transistor which is not selected during read or from a memory cell transistor in a written state causes read errors. This leakage current increases as the gate length of a select transistor and memory cell transistor decreases. This is so because the off-leakage current of a transistor increases by the short channel effect. In particular, the cutoff characteristic of a select transistor is an important parameter.

In this embodiment, the short channel effect improves by the increase in gate electrode width, and this reduces the leakage current, so the margin to read errors improves. In particular, the gate lengths of not only the memory cell transistors M0 to M15 but also the select transistors S1 and S2 can be increased without changing the NAND length, i.e., the distance between the contact of the source line SL and the contact of the bit line BL. This makes it possible to increase the density and improve the read characteristics of the semiconductor memory at the same time.

(E) Fifth Embodiment

A nonvolatile semiconductor memory according to the fifth embodiment of the present invention will be described below.

In this embodiment, the semiconductor memory structure of the second embodiment is used in a NAND cell array. Note that the same reference numerals as in the second embodiment denote the same elements, and an explanation thereof will be omitted. Note also that an equivalent circuit configuration and a planar arrangement are similar to those shown in FIGS. 23 and 24, so an explanation thereof will be omitted.

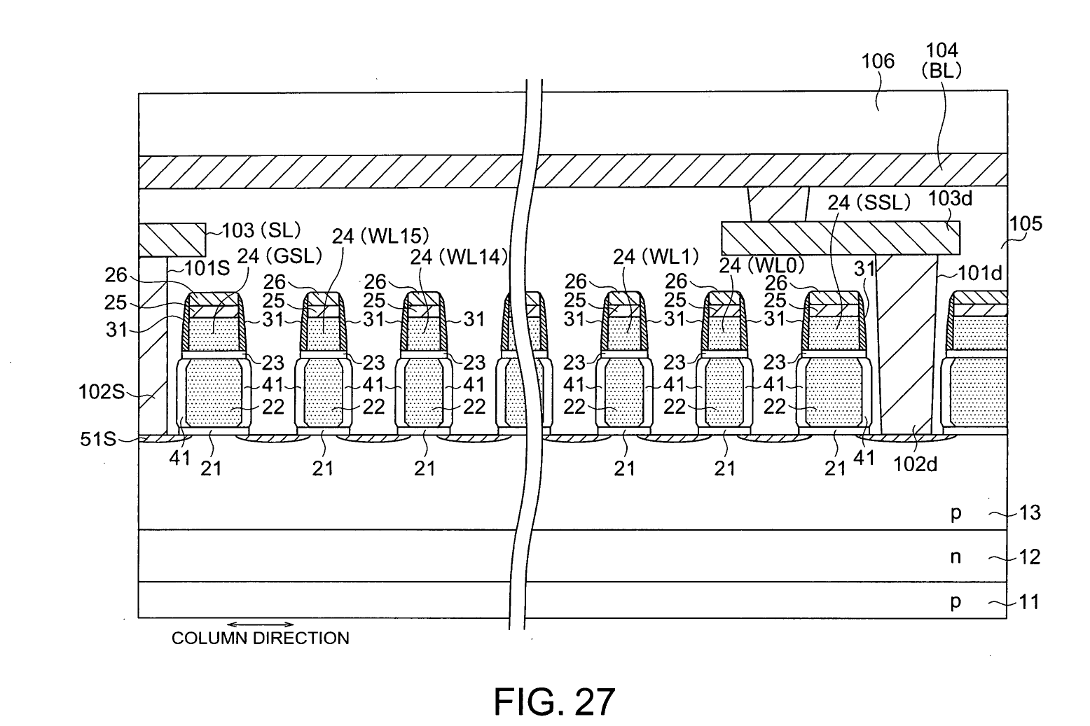

FIG. 27 shows a longitudinal section taken along the line A-A in FIG. 24.

As in the second embodiment, the sidewalls of a mask insulating film 26, control gate resistance decreasing metal film 25, and control gate electrode 24 are covered with a sidewall insulating film 31 made of, e.g., a 2- to 20-nm thick silicon nitride film or silicon oxynitride film.

A sidewall insulating film 41 made of a silicon oxide film is formed on the sidewalls of a floating gate electrode 22. N-type impurity diffusion layers 51 serving as source and drain regions are also formed.

The impurity diffusion layers 51, floating gate electrode 22, and control gate electrode 24 form a floating gate type EEPROM cell in which a charge amount stored in the floating gate electrode 22 is used as an information amount.

This embodiment has characteristic features (12) and (13) explained in the fourth embodiment in addition to the characteristic features of the second embodiment.

(F) Sixth Embodiment

A nonvolatile semiconductor memory according to the sixth embodiment of the present invention will be described below.

In this embodiment, the semiconductor memory structure of the third embodiment is used in a NAND cell array. Note that the same reference numerals as in the second embodiment denote the same elements, and an explanation thereof will be omitted. Note also that an equivalent circuit configuration and a planar arrangement are similar to those shown in FIGS. 23 and 24, so an explanation thereof will be omitted.

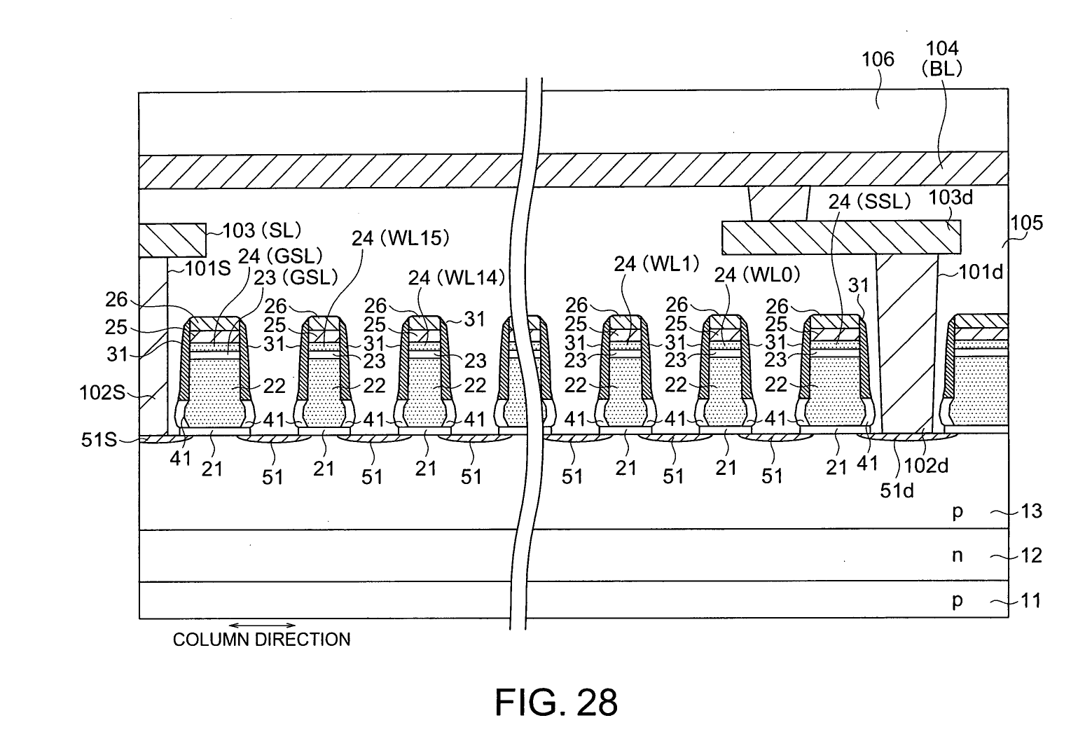

FIG. 28 shows a longitudinal section taken along the line A-A in FIG. 24.

As in the third embodiment, the sidewalls of a mask insulating film 26, control gate resistance decreasing metal film 25, control gate electrode 24, and interpoly insulating film 23 and the sidewalls of the upper portion of a floating gate electrode 22 are covered with a sidewall insulating film 31 made of, e.g., a 2- to 20-nm thick silicon nitride film or silicon oxynitride film.

A sidewall insulating film 41 made of a silicon oxide film is formed on the sidewalls of the lower portion of the floating gate electrode 22. N-type impurity diffusion layers 51 serving as source and drain regions are also formed.

The impurity diffusion layers 51, floating gate electrode 22, and control gate electrode 24 form a floating gate type EEPROM cell in which a charge amount stored in the floating gate electrode 22 is used as an information amount.

This embodiment has characteristic features (12) and (13) explained in the fourth and fifth embodiments in addition to the characteristic features of the third embodiment.

As described above, in the nonvolatile semiconductor memory according to each embodiment, the sidewalls of the metal layer forming the control gate electrode are covered with the sidewall insulating film. In the gate sidewall oxidation step, therefore, this metal layer does not abnormally oxidize, so the normal shape and dimensions as a gate electrode can be maintained. Accordingly, impurity diffusion layers can be normally formed by ion-implanting an impurity by using the gate electrode as a mask after that, and this improves the yield.

The above embodiments are merely examples and hence do not limit the present invention. For example, the method of forming the element isolation films and insulating films is not limited to the method of the above embodiments in which silicon is converted into a silicon oxide film or silicon nitride film, and it is also possible to use, e.g., a method of injecting oxygen ion into deposited silicon or a method of oxidizing deposited silicon.

In addition, the interpoly insulating film 23 may also be a TiO₂ film, Al₂O₃ film, tantalum oxide film, strontium titanate film, barium titanate film, zirconium lead titanate film, ZrSiO film, HFSiO film, ZrSiON film, or HFSiON film, or a stacked film having at least two layers of any of these films.

The sidewall insulating film 31 and mask insulating film 26 need only be oxidation-resistant insulating films. Examples are an Al₂O₃ film, ZrSiO film, HFSiO film, ZrSiON film, HFSiON film, Si film, or SiON film, or a stacked film having at least two layers of any of these films.

In each of the above embodiments, a P-type substrate is used as a semiconductor substrate. However, this semiconductor substrate can be any silicon-containing single-crystal semiconductor substrate. Examples are an N-type semiconductor substrate, an SOI silicon layer of an SOI substrate, an SiGe mixed crystal layer, and an SiGeC mixed crystal layer.

Furthermore, although an N-type MOSFET is formed on a P-type semiconductor substrate in each of the above embodiments, a P-type MOSFET may also be formed on an N-type semiconductor substrate. In this case, N-type and P-type in the above embodiments are replaced with P-type and N-type, respectively, and a doping impurity As, P, or Sb in the above embodiments is replaced with IN or B.

Also, as the control gate electrode, it is possible to use an Si semiconductor, SiGe mixed crystal, or SiGeC mixed crystal, or a stacked structure of these materials.

As the control gate resistance decreasing metal film, it is possible to use silicide or polycide such as TiSi, NiSi, CoSi, TaSi, Wsi, or MOSi, or a metal such as Ti, Al, Cu, TiN, or W.

Each of the above embodiments is explained by taking a NAND semiconductor memory as an example. However, the first to third embodiments are also applicable to a NOR semiconductor memory or a stand-alone semiconductor memory.

When W is used as the control gate resistance decreasing metal film, a 0.5- to 10-nm thick barrier metal made of, e.g., WN or Wsi is desirably formed between this control gate resistance decreasing metal film and the control gate electrode, in order to prevent unevenness of the interface in a heating step performed after the gate structure is stacked.

Moreover, the above embodiments can be variously modified without departing from the technical scope of the present invention.

1. A nonvolatile semiconductor memory capable of electrically writing and erasing information, comprising:
a semiconductor substrate;
source and drain regions formed at a predetermined spacing in a surface portion of said semiconductor substrate;
a channel region positioned between said source and drain regions;
a floating gate electrode formed on said cannel region via a first insulating film;
a control gate electrode including a semiconductor layer formed on said floating gate electrode via a second insulating film, and a metal layer formed on said semiconductor layer; and
an oxidation-resistant third insulating film formed on said control gate electrode,
wherein the nonvolatile semiconductor memory further comprises an oxidation-resistant fourth insulating film so formed as to cover at least sidewalls of said metal layer, and
said fourth insulating film is formed from the sidewalls of said metal layer to at least portions of sidewalls of said semiconductor layer of said control gate electrode.

2. A nonvolatile semiconductor memory, comprising:
a semiconductor substrate;
source and drain regions formed at a predetermined spacing in a surface portion of said semiconductor substrate;
a channel region positioned between said source and drain regions;
a floating gate electrode formed on said cannel region via a first insulating film;
a control gate electrode including a semiconductor layer formed on said floating gate electrode via a second insulating film, and a metal layer formed on said semiconductor layer;
an oxidation-resistant third insulating film formed on said control gate electrode; and
an oxidation-resistant fourth insulating film formed as to cover sidewalls of said metal layer, and to cover regions from sidewalls of said semiconductor layer of said control gate electrode to portions of sidewalls of said floating gate electrode.

3. A memory according to claim 2, wherein a fifth insulating film is formed on at least portions of the sidewalls of said floating gate electrode by oxidizing a charge storage electrode, and
in portions of said floating gate electrode where said fifth insulating film is in contact with said first insulating film on the sidewalls of said semiconductor layer, a thickness of said fifth insulating film is made larger than that in portions where said fifth insulating film is not in contact with said first or second insulating film.

4. A memory according to claim 3, wherein said fifth insulating film is made of a material selected from the group consisting of a silicon oxide film and silicon nitride film, and has an oxygen composition larger than that of said fourth insulating film.

5. A memory according to claim 4, wherein said metal layer is made of a material selected from the group consisting of W and WSi.

6. A memory according to claim 5, wherein said metal layer is made of WSi having an Si/W ratio of not more than 2.2.

7. A memory according to claim 6, wherein said fourth insulating film is made of a silicon nitride film.

8. A memory according to claim 1, wherein said fourth insulating film is formed above an interpoly insulating film.

9. A nonvolatile semiconductor memory fabrication method, comprising:
forming, on a semiconductor substrate, a first insulating film, a conductive film serving as a floating gate electrode, a second insulating film, a semiconductor layer and metal layer serving as a control gate electrode, and a third insulating film in the order named;
patterning the third insulating film, the metal layer, and an upper portion of the semiconductor layer into a shape of a gate electrode;
forming a fourth insulating film on surfaces of the third insulating film, metal layer, and semiconductor layer;
etching the fourth insulating film such that the fourth insulating film remains on sidewalls of the third insulating film, metal layer, and semiconductor layer, and does not remain on an upper surface of the semiconductor layer;
etching and patterning the semiconductor layer, metal layer, second insulating film, and conductive film into a shape of an electrode by using the third insulating film as a mask, thereby forming the floating gate electrode and control gate electrode;
performing a post-oxidation process to form a sidewall oxide film on portions of sidewalls of the semiconductor layer, which are not covered with the fourth insulating film, and on sidewalls of the conductive film; and
ion-implanting an impurity in a surface portion of the semiconductor substrate by using the floating gate electrode and control gate electrode as masks, thereby forming source and drain regions.
